(19) United States
(12) Patent Application Publication
(10) Pub. No.: US 2026/0196129 A1
(43) Pub. Date: Jul. 9, 2026

(54) SYSTEMS AND METHODS FOR MANAGING ELECTRICAL AND INTERNAL COMBUSTION VEHICLES

(71) Applicant: Stephen William COWPER, Suffolk (GB)

(72) Inventor: Stephen William COWPER, Suffolk (GB)

(21) Appl. No.: 18/875,401

(22) PCT Filed: Jun. 15, 2023
(86) PCT No.: PCT/GB2023/051578

§ 371 Date: Dec. 16, 2024

(30) Foreign Application Priority Data
Jun. 15, 2022 (GB) 2208813.2

(51) Int. Cl. G08G 1/015; G01J 5/00; G01J 5/10; G01R 33/02; G06Q 30/04; G08G 1/017; G08G 1/02; G08G 1/04; G08G 1/042; H02S 20/30

(52) U.S. Cl. CPC G08G 1/015; G01J 5/10; G01R 33/0206; G06Q 30/04; G08G 1/017; G08G 1/02; G08G 1/04; G08G 1/042; G01J 2005/0077; G01J 2005/106; G06Q 2240/00; H02S 20/30

(57) ABSTRACT

There is disclosed a computerized method of managing access of electric vehicles (EVs) or of internal combustion engine vehicles (ICEs) into parking bays using a computerized system comprising parking-sensor pucks with communication capabilities, connected to a remote server. The parking-sensor pucks, each installed on corresponding parking bays, comprise a thermal sensor configured to measure at least one value representative of a temperature of an underside of a vehicle and a magnetometer configured to measure at least one value representative of magnetic field at the magnetometer. The method comprises processing said at least one temperature value and/or magnetic field value, and, based on said processing, performing at least a selective determination of whether an EV or an ICE has entered a given parking space. In this way, parking bays specifically provided for EVs, for example for charging purposes, may be efficiently managed.

### TECHNICAL FIELD

The present application relates to a system for managing electrical vehicle (EV) charging bays. In particular, the present application relates to a system for managing EV charging bays that can detect an ‘intruder’ internal combustion engine (ICE) vehicle. The present application also relates to deterrent methods to reduce the number of ICE vehicles using EV designated charging bays. Further, the present application also relates to a system for, and a method of, identifying EVs which are not currently using a charge point, as well as systems for, and methods of, preventing said EVs from blocking said charging point. A method of identifying ICE vehicles and EVs is also covered, along with a system for managing access to restricted traffic areas such as Low Emissions Zones.

### BACKGROUND

There has been a significant increase in the number of EVs sold in the UK. In 2018 2.5% of new cars sold in the UK were plug-enabled EVs, this has increased to over 10% in 2020. This market share is increasing rapidly as new models of EV become available. The increase in the number of EVs being sold has necessitated an increase in the number of public charging points and designated plug-enabled EV charging bays. This has resulted in the rise of an issue referred to as ‘ICEing’. The term ‘ICEing’ refers to a petrol-or diesel-powered vehicle parking in an EV charging bay. This causes an issue in accessing charging points for EV users. This issue may continue despite clear signage threatening parking fines for those misusing EV designated spaces.

There are some existing methods which seek to provide a solution to this problem. One such example is a service offered by UK based EV Parking Management. Using existing Automatic Number Plate Recognition (ANPR) methods, EV Parking Management checks the number plate of a vehicle in a designated EV charging space against a vehicle registration database to determine whether it is an EV or an ICE vehicle. If an ICE vehicle is identified, the system then triggers an automated fine such as done by standard parking enforcement. An additional, similar example can be found (at the date of writing) at internet URL: https://www.nationalparkingcontrol.co.uk/services/car-park-management/electric-charging-bays.

There are several drawbacks to these solutions, the main two being that they are expensive and require good internet connection to continually check through the vehicle registration database. These requirements may be prohibitive for most sites, particularly in urban areas or at ‘Destination Chargers’ such as at hotels, supermarkets, restaurants, where typically only a comparatively low number of charging points are in place.

A further solution is offered by parking technology provider Circontrol. This solution uses standard sensing techniques to identify when an EV specific charging bay is occupied and issues an alert if a charging session is not initiated. As with the previously discussed solutions, this solution is also not feasible in more remote or sparsely occupied sites.

### Statement of Invention

According to an aspect of the present disclosure there is provided a computerized system for selectively determining access of an electric vehicle (EV) or of an internal combustion engine (ICE) vehicle into a predetermined zone of interest. The system comprises at least one thermal imaging camera configured to acquire at least one thermal image. The thermal image comprises at least a portion of said vehicle as well as a region of said interest zone. The system is configured to perform said selective determination based on a processing of said thermal image.

In an arrangement of the present disclosure, the predetermined zone of interest comprises one or more EV charging bays. The system may additionally comprise one or more EV charging points, each EV charging point being optionally associated with a respective EV charging bay. The present application therefore sets forth an innovative, effective and low-cost solution to the problem of identifying and deterring non-EV vehicles occupying designated EV charging bays. As a consequence, EV users can have greater access to charging points while also enabling charge point operators to maximize the use of their assets. In a further arrangement, said predetermined zone of interest comprises a restricted traffic zone, such as a Low Emission Zone.

The thermal image camera may be installed in or on the respective EV charging point, or alternatively at a location nearby said respective EV charging point. The thermal imaging camera may be arranged to cover a single EV charging bay. Alternatively, the thermal imaging camera may be arranged to cover a plurality of EV charging bays.

It is well known that during operation the engine and exhaust systems of an ICE vehicle will generate a significant amount of heat. This results in hot spots in specific areas, generally the front grille, bonnet and exhaust system, including on the whole or at least part of the vehicle underside. Comparatively, the drive mechanism of an EV generates significantly less heat during operation. While the battery, motor and brake system of the EV will generate some heat, it is a measurably lower level than that of ICE vehicles.

The thermal imaging camera may, therefore, be configured to capture one or more of:
a vehicle's bonnet
a vehicle's grille;
a vehicle's rear side; and
a vehicle's underside,

(i.e. a relatively ‘hot’ part of the vehicle, or a part of the vehicle that includes a relatively ‘hot’ part of the vehicle, if the vehicle has an ICE) as well as, optionally, a part of the remainder of the vehicle's body (i.e. a relatively ‘cold’ part of the vehicle).

The processing of said thermal image may comprise the determination of one or more parameters calculated from values representative of respective temperatures associated with said thermal image.

Said parameters may comprise at least one of the following:
a difference
a gradient
a peak; or
a mean.

Further, said processing may comprises a comparison of said one or more parameters with one or more reference values for said parameters. The reference values may be arbitrarily inputted by a user. Said reference values may also be derived from a background thermal image acquired prior to the vehicle accessing said interest zone, and preferably immediately prior to said vehicle accessing said interest zone. However, said reference values may simply be derived from ‘cold’ zones in said thermal image associated with the region of interest rather than with presence of the vehicle.

For example, the system may be configured to identify ICE vehicles based upon the higher temperature captured by the thermal imaging camera compared to similar images captured of EVs. The thermal imaging camera may also be arranged to capture a reference snapshot of an empty charging bay.

The processing of the captured thermal image may comprise the definition of one or more superpixels, wherein each superpixel comprises a cluster of neighbouring pixels of said thermal image satisfying a predetermined variance criterion. As such, the hottest and/or coldest areas of the thermal image, and therefore of the occupying vehicle, may be identified. The system may be configured to then identify the type of vehicle occupying a charging bay based upon said thermal variation and/or distribution.

The system may additionally comprise a sensor configured to sense ingress of the vehicle into said interest zone. The sensor may be arranged to detect a vehicle approaching the EV charging bay. Upon detecting the vehicle, the system may be configured to initiate capture of the charging bay by the thermal imaging camera directly prior to occupation and upon arrival of the vehicle in the charging bay.

Upon detection of an ICE vehicle having entered the interest zone the system may be configured to produce a deterrent audio and/or visual output, notifying the user of the ICE vehicle of their infraction. The system may also be configured to initiate a penalty process if the system has determined that an ICE vehicle has entered the interest zone. Optionally, said penalty process may be initiated after the production of said deterrent audio/visual output and expiration of a predetermined grace time period. The system may also be configured to issue the deterrent audio and/or visual output and/or to initiate the penalty process if the system has determined that an EV has parked in an EV charging bay, and the EV has not commenced a charging operation at an EV charging point. The initiation of the penalty process may, optionally, occur following expiration of a predetermined grace time period.

The penalty process may comprise monitoring a number of infringements during a period of time; this could be done, for example, for a given vehicle. Additionally, or alternatively, the penalty process may comprise notifying via electronic means physical enforcement officers to attend the site to issue a ticket in person. Ultimately, a fully automated enforcement solution as described herein may be provided.

According to another aspect of the present disclosure, there is provided a parking-sensor puck for selectively determining access of an electric vehicle (EV) or of an internal combustion engine vehicle (ICE) into a parking bay, the parking-sensor puck comprising:
a thermal sensor configured to measure at least one value representative of a temperature on an underside of said vehicle;
a magnetometer configured to measure at least one value representative of magnetic field at the parking sensor puck; and,
a wireless transmitter for communicating said values to a server.

The puck may further comprise a passive infrared sensor configured to detect presence of an obstruction located in the space above the puck, and to awake the thermal sensor and/or the magnetometer in the presence of said obstruction.

The thermal sensor may be a pyroelectric sensor. However, in preferred arrangements, the thermal sensor is an array-type infrared thermal sensor configured to acquire a plurality of values representative of a plurality of corresponding temperatures taken on said vehicle underside. Accordingly, any hot spots related to, and characterizing, an ICE will be more likely detected.

In a further preferred arrangement, the array-type infrared thermal sensor is a (full) infrared thermal imaging camera configured to acquire a thermal image of at least a portion of said vehicle underside, or of all the vehicle underside, depending on optical settings of the thermal imaging camera. Infrared imaging cameras are nowadays commonly available off-the-shelf, and come in a range of suitable specifications.

The magnetometer may be a three-axis magnetometer, measuring components of a magnetic field in three nominal directions: x, y and z.

Preferably, the puck comprises Global Navigation Satellite System (GNSS) capabilities, so that location information may be available, if required.

Preferably, the puck will be battery operated and the battery may be a rechargeable battery. For the sake of autonomy, the puck may comprise a light-harvesting device configured to recharge said rechargeable battery. For example, said device may be capable of harvesting sunlight, or artificially produced light.

The wireless transmitter may be configured to communicate said values over one or more of a plurality of convenient connections, such as: a Low Power Wide Area connection (LPWA); a cellular connection; a Long Term Evolution for Machines connection (LTE CatM); a Narrow Band Internet of Things connection (NB-IoT), such as a Long Range Wide Area Network connection (LoRaWAN); and, a Bluetooth Low Energy connection (BLE).

According to a further aspect of the present disclosure, there is also provided a system comprising a plurality of parking-sensor pucks as described herein, and at least one gateway for collecting said values from the plurality of said parking-sensor pucks and for forwarding said values on to a server, as also described herein.

Optionally, the at least one gateway and the plurality of parking-sensor pucks are configured to communicate over a BLE connection, which is a particularly energy-saving arrangement.

Optionally, it is the gateway that is configured to communicate to the server over one or more of the other connections referenced herein, i.e., said LPWA, connection using either a licensed cellular transmission connection such as a LTE CatM/NB-IoT connection, or unlicensed bands such as a LoRaWAN connection; or, the gateway could communicate with the one or more servers using a WiFi connection to a nearby access point.

According to a further aspect of the present disclosure, there is also provided a computerized system for managing access of electric vehicles (EVs) or of internal combustion engine vehicles (ICEs) into parking bays, the system comprising:
at least one parking-sensor puck as described herein in operable communication with at least one server, each parking-sensor puck being installed on a corresponding parking bay; and/or,
at least one system as described herein in operable communication with at least one server, each parking-sensor puck being installed on a corresponding parking bay;
wherein the computerized system is configured to selectively determine whether an EV or an ICE vehicle has entered a parking bay based on a processing of at least one of said values measured by a corresponding parking-sensor puck.

In preferred arrangements, said processing may comprise determining one or more parameters calculated from said values representative of a plurality of temperatures taken on said vehicle underside.

Further, any features disclosed in connection with any one of the aspects described above may be used also in connection with the other aspects of the present disclosure-unless technical impediments to do so apply, as it would be recognized by the skilled person.

According to a preferred arrangement, the computerized system may be additionally configured to determine whether the EV is charging, if the system has determined that an EV has entered the parking bay. This may be accomplished by considering either the thermal values or the magnetic values, or, more preferably, both.

In a further preferred arrangement, the computerized system may be configured to monitor usage of the parking bays by the EVs and ICEs. Accordingly, the computerized system may be configured to generate and, optionally, to display, statistics, charts, summaries and the like pertaining to the usage of the parking bays over periods of time, including occupancy times for EVs, ICEs, charge times, and so on.

According to a further aspect of the present disclosure, there are also provided computerized methods of managing and/or monitoring access of electric vehicles (EVs) or of internal combustion engine vehicles (ICEs) into parking bays using computerized systems as described herein.

Finally, according to yet further aspect of the present disclosure, there are also provided one or more computer media comprising coded instructions implementing, when executed by a computer, a method as described herein.

### DRAWINGS

Illustrative implementations will now be described, by way of example only, with reference to the accompanying drawings. In the drawings:

FIG. 1 shows a system as described herein, applied to three designated EV charging bays;

FIG. 2 illustrates different statuses of the system referred to in FIG. 1;

FIG. 3a is a thermal image of an ICE vehicle post operation;

FIG. 3b is a thermal image of an EV post operation;

FIG. 4 is a chart representing physical and logical blocks of a system as described herein;

FIG. 5a is a thermal image of a portion of an ICE vehicle, divided into 12 sections;

FIG. 5b is an array of 12 ‘superpixels’, calculated from the thermal image of FIG. 5a and denoting the mean temperature of each superpixel;

FIG. 6a is a thermal image of a portion of an EV, corresponding approximately to the portion referred to in FIG. 5a, also divided into 12 sections;

FIG. 6b is an array of 12 superpixels, calculated from the thermal image of FIG. 6 a, denoting the mean temperature of each superpixel;

FIG. 7 is a flowchart illustrating a process of vehicle identification and issuance of warning and penalties, as described herein;

FIG. 8 depicts a plurality of possible locations for the installation of the system referred to in FIG. 1, on an EV charging station;

FIG. 9 shows another example of a system as described herein, wherein charging stations are offset from charging bays;

FIG. 10 is a thermal image of two ICE vehicles parked in two charging bays;

FIG. 11 is a thermal image of the rear tailpipe of an ICE vehicle while driving;

FIG. 12 is a thermal image of a portion of an ICE vehicle while driving;

FIG. 13 is a thermal image of a portion of an EV while driving;

FIG. 14 shows on a map the location of certain EV charging facilities, with their statuses and summaries of penalties issued or prevented;

FIG. 15 is a perspective view of a parking-sensor puck as described herein;

FIG. 16 is a cross-sectional view of the parking-sensor puck of FIG. 15, showing internal components;

FIG. 17 represents two parking bays with respective parking-sensor pucks installed at the centre thereof, one without a vehicle therein and one with an incoming vehicle;

FIG. 18 schematically represents a computerized parking monitoring system as described herein, based on the use of one parking-sensor puck;

FIG. 19 schematically represents a computerized parking management system as described herein, based on the use of multiple parking-sensor pucks;

FIGS. 20a and 20b show, respectively, a visual image and a corresponding thermal image portions of an underside of an ICE vehicle;

FIG. 21 shows three signals referring to the x, y and z components of the magnetic field measured by a magnetometer incorporated into the parking-sensor puck of FIGS. 15 and 16 in connection with two EV parking events;

FIG. 22 shows three signals referring to the x, y and z components of the magnetic field measured by the same magnetometer of FIG. 20 in connection with an ICE parking event; and,

FIG. 23 shows three signals referring to the x, y and z components of the magnetic field measured by the same magnetometer of FIGS. 21 and 22, in connection with two EV charging events.

Throughout the description and drawings, like reference numerals refer to like features.

### DETAILED DESCRIPTION

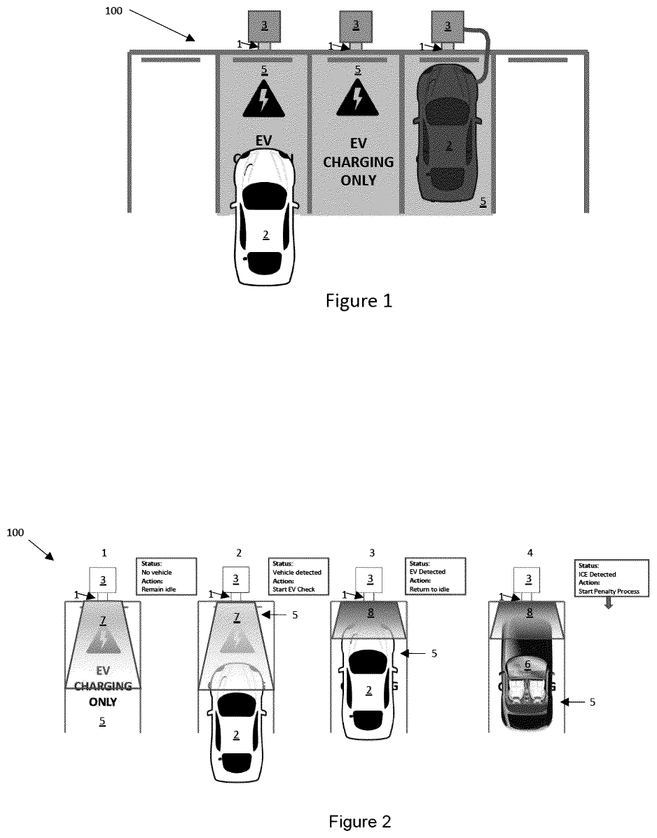

FIG. 1 shows a system 100 for managing electric vehicle EV 2 designated charging bays 5. Three EV charge points 3, each corresponding to an EV charging bay 5 are shown in FIG. 1. One EV 2 is shown entering an EV charging bay 5 and a second EV 2 is shown connected to a charge point 3. A data acquisition box 1 is shown attached to the charging point 3. The data acquisition box 1 may comprise at least one of:
a thermal imaging camera 13
a physical presence sensor 11
a conventional camera 21
an image capture module 22
a thermal image processing module 15
an EV/ICE determination module 16
a grace period timer 19

Although not shown, the components of the data acquisition box may, also, be integrated into the charging point.

In FIG. 2 the system 100 is shown as being in a status of “No vehicle”. The system 100 is in the “No vehicle” status when the charging bay 5 is unoccupied. The system 100 is arranged to identify an empty charging bay 5 and, in response, to remain idle. It should be noted that when idle, the system 100 is arranged to detect an incoming physical body. In FIG. 2 the system 100 is additionally shown as being in a status of “Vehicle detected”. The system 100 enters the “Vehicle detected” status upon detecting an incoming physical body. The incoming physical body is detected by the system 100 once it is within range 7 of the physical presence sensor 11. Once the physical body is within range 8 of the thermal image camera 13 the system initiates identification of the physical body. As shown in FIG. 2, the range 7 of the physical presence sensor 11 is greater than the range 8 of the thermal image camera 13. The difference in range is such that there is sufficient delay between a vehicle being registered by the physical presence sensor 11 and the vehicle entering the range 8 of the thermal image camera 13 for the system to capture at least a section of the charging bay 5 immediately prior to occupation. When in the “Vehicle detected” status the system 100 proceeds to identify the type of vehicle, i.e. EV 2 or internal combustion engine vehicle (ICE) 6. If the system 100 identifies the vehicle in the charging bay 5 as an EV vehicle 2, the system 100 enters the “EV Detected” status. When in the “EV Detected” status the system 100 is idle. Alternatively, if the system 100 identifies the vehicle in the charging bay as an internal combustion engine vehicle (ICE) 6, the system 100 enters the “ICE Detected” status. Upon entering the “ICE Detected” status the system 100 is arranged to initiate a penalty process. It should be noted that upon a hybrid vehicle entering the charging bay 5 the response of the system 100 will be dependent upon the power source used by the vehicle, and the resultant thermal signature, directly prior to entering the charging bay 5. If the hybrid vehicle has arrived in the charging bay 5 under the power of a battery, the system 100 will identify the hybrid vehicle as an EV 2 and respond accordingly. If the hybrid vehicle has arrived in the charging bay 5 under the power of an ICE, the system will identify the hybrid vehicle as an ICE vehicle 6 and respond accordingly.

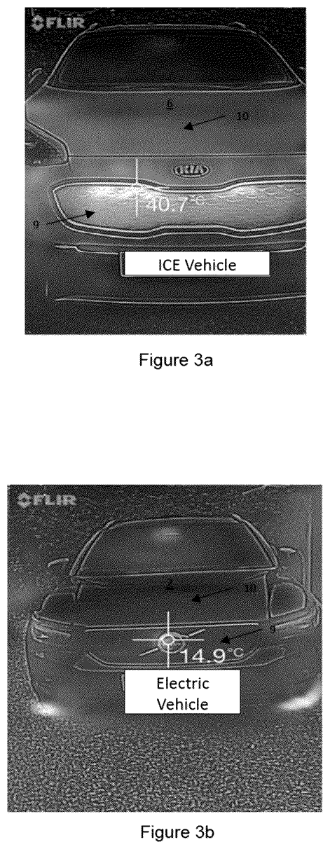

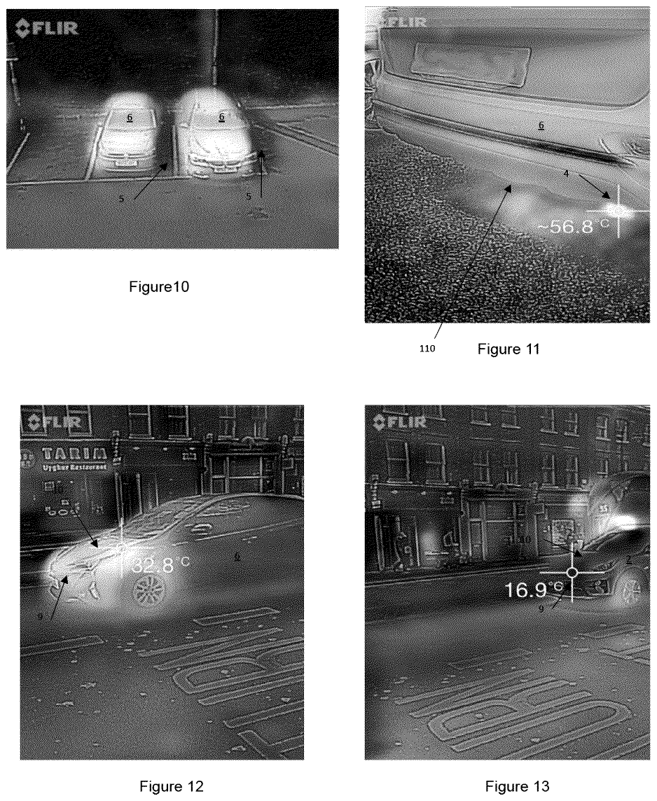

The system 100 described herein is arranged to identify the vehicle type entering the charging bay 5 based upon the heat distribution of the vehicle. During, and immediately after, operation the drive mechanism of an ICE vehicle 6 generates a significantly higher amount of heat when compared with the heat generated by an EV 2 during operation. The system 100 is arranged to identify the type of vehicle present by examining the heat distribution of the vehicle and comparing it with system 100 acquired values for an unoccupied charging bay 5, or alternatively with a user defined set of values reflective of those consistent with an EV 2 or ICE vehicle 6. In particular, a significant amount of heat is generated around the bonnet 10, front grille 9 and exhaust 4 areas as well as the underside of the vehicle. Conversely, the battery of an EV 2 generates a comparatively small amount of heat. With reference to the thermal images of FIGS. 3a and 3b, the post operation temperatures of the front grilles 9 of an ICE 6 and an EV 2 are shown. FIG. 3a shows the temperature of the front grille 9 of the ICE 6 to be 40.7 degrees Celsius. The temperature of the front grille 9 of the EV 2 is 14.9 degrees Celsius. In addition, FIG. 11 is a thermal image of the exhaust system 4 of an ICE 6, the temperature of which is, as shown, 56.8 degrees Celsius. Therefore, the system 100 is able to identify the vehicle type of a vehicle facing the system 100, or reversing towards the system 100.

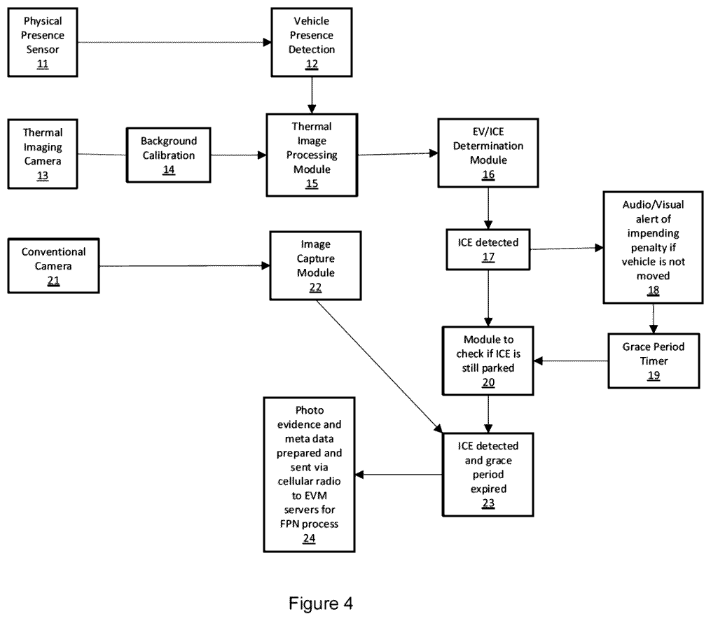

The physical and logical blocks of the system 100 described herein are schematically represented in FIG. 4. The physical presence sensor 11 is shown. The physical presence sensor 11 is arranged to detect vehicle presence 12 in the EV charging bay 5. The sensor 11 may, for example, use existing long range proximity sensor methods to detect an object being nearby. The sensor may also, for example, use Deep Neural Nets methods to detect a vehicle while also identifying the make and model of said vehicle. Further examples of existing capabilities which may be applied by the sensor 11 include ultrasonic, time of flight, magnetic and visual sensing. The physical presence sensor 11 may be configured to be ultra-low power. The physical presence sensor 11 may optionally, be solar or battery powered. The system 100 also comprises a thermal imaging camera 13. The thermal imaging camera 13 may, for example, be a low-cost FLIR Lepton Sensor or alternative thermographic sensors that can capture thermal images. The thermal imaging camera 13 is arranged to capture thermal images such as those shown in FIG. 3a and FIG. 3b. The thermal imaging camera 13 may be arranged to capture the thermal distribution of an occupied charging bay 5. The system 100 also comprises a thermal image processing module 15. The module 15 may be arranged to receive a plurality of inputs. One such input may be the detection of vehicle presence, received from the physical presence sensor 11. A further input may be the thermal images captured by the thermal imaging camera 13. In addition to receiving the thermal images of, for example, an occupied charging bay 5 the thermal image processing module 15 may also be arranged to receive a background calibration input 14. The background calibration input 14 may be a thermal capture of the unoccupied charging bay 5. The thermal imaging camera 13 may be arranged to periodically capture the thermal distribution of the charging bay 5, thus capturing the thermal distribution of the unoccupied charging bay 5. The frequency of this capture may be specified by the user or the system. The thermal imaging camera 13 may also initiate capture of the charging bay 5 upon detection of an approaching vehicle by the physical presence sensor 11. The thermal image processing module 15 may thereafter be configured to compare the thermal distribution of the charging bay 5 directly prior to occupation with the thermal distribution of the charging bay 5 when occupied. Consequently, the system 100 may be configured to ascertain one or more, or all, of a variety of metrics such as:
Maximum spot temperature;
Difference between average temperature of the reference snapshot to the maximum spot temperature; and
Mean temperature of the image across all pixels.

With continued reference to FIG. 4, the system 100 further comprises an EV/ICE determination module 16. The EV/ICE determination module 16 is arranged to receive an input from the thermal image processing module 15 and accordingly, identify whether a vehicle is an ICE 6 or an EV 2. As discussed previously, an EV 2 is identifiable by its comparatively lower heat emissions whilst an ICE 6 is identifiable by its comparatively higher heat emissions. The system 100 may, for example, identify the vehicle type based upon the metrics listed above.

The system 100 may also be arranged to emit an audio/visual alert 18. Upon detection 17 of an ICE 6 in the designated EV charging bay 5 the system 100 may be arranged to issue the audio/visual alert 18. This alert may indicate an impending penalty if the ICE 6 is not removed from the EV charging bay 5. The system 100 may optionally be arranged to transmit the data captured by the system 100. The data could, for example, be transmitted via a radio, modem or cloud systems. The data may, optionally, be transmitted to Electrical Vehicle Management (EVM) for onwards penalty processing, such as with existing automatic number plate recognition (ANPR) capabilities. The data may also be transmitted, for example, to a local parking attendant to notify them of a parking infraction. The system 100 may also incorporate a user or system 100 defined grace period, whereby if the vehicle is removed from the charging bay 5 within the grace period no penalty is issued and, optionally, no data transmitted. The system may comprise a grace period timer 19. The grace period timer 19 may be initiated upon issuance of the audio/visual alert 18. The system 100 may, additionally, comprise a module 20 configured to detect if the ICE vehicle 6 is parked in the EV designated charging bay 5 after the grace period has expired. The module 20 may, for example, receive an input from the physical presence detector 11 and/or the thermal imaging camera 13. The system 100 is therefore configured to detect if a physical presence is in the bay after the grace period has expired and to, optionally, confirm that the physical presence is the ICE 6 previously detected.

Additionally, the system 100 may comprise a conventional camera 21. The conventional camera 21 may be arranged to capture the EV charging bay 5. The conventional camera 21 may be configured to capture the EV charging bay 5 dependent upon receiving a variety of inputs. For example, the conventional camera 21 may be configured to capture the EV charging bay 5 upon detection of a vehicle occupying the charging bay 5 by the physical presence detector 11. The conventional camera 21 may also, for example, be configured to capture the charging bay 5 following identification of an ICE 6 by the EV/ICE determination module 16. The conventional camera 21 may also output the captured image to the image capture module 22. The conventional camera 21 may also, for example, be configured to capture the charging bay 5 upon expiry of the grace period. Upon detection of the ICE 6 in the charging bay 5 after the grace period has expired 23 the capture, including the offending vehicle number place, may be compiled into a data pack. The data pack may be transmitted 24 for further processing and penalty issuance. The data pack may be transmitted 24, for example, to said EVM or parking attendant. Alternatively, the capture of the offending vehicle may be deleted following departure of the vehicle within the grace period. In the scenario in which the vehicle is captured prior to vehicle identification by the EV/ICE determination module 16, the photo may be deleted following identification of the vehicle as an EV 2.

In a variation, the system 100 may be configured to recognize that it is indeed a vehicle (as opposed to a person, or other object) that has entered the interest zone, via said conventional camera 21. In this case, the system 100, for example the conventional camera 21 itself, may be equipped to do so using a pre-trained deep neural network DNN. It is known in the arts to train DNNs to recognize vehicles, and accordingly this will not be described further herein.

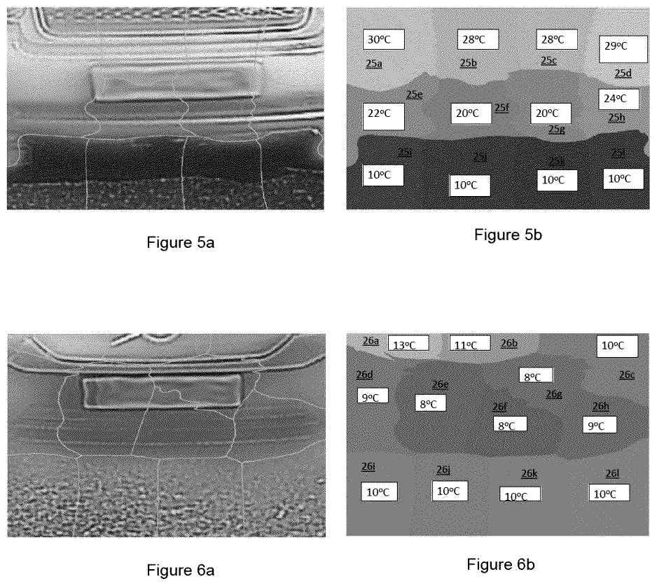

The system 100 may further process a thermal image capture using existing techniques. Using one such technique, the thermal image processing module 15 may be configured to define a set of Regions of Interest (ROIs) within the captured thermal image, as shown in FIGS. 5 and 6. The thermal image processing module 15 may, additionally or alternatively, be configured to calculate ‘superpixels’ 25, 26 from the captured thermal image and to, therefore, determine the mean temperature of similar temperature pixel regions. These superpixels 25, 26 are determined based on temperature gradients between regions with similar thermal properties. FIG. 5a illustrates an example thermal capture of an ICE 6. FIG. 5b illustrates an array of 12 superpixels 25 calculated from the thermal image of FIG. 5 a, including the mean temperature of the area of the thermal capture represented by each superpixel 25. Similarly, FIG. 6a illustrates an example thermal capture of an EV 2. FIG. 6b illustrates an array of 12 superpixels 26 calculated from the thermal image of FIG. 6 a, including the mean temperature of the area of the thermal capture represented by each superpixel 26. With reference to FIG. 5b the temperature variation between the mean temperature of the superpixels 25i, 25j, 25k, 25l representative of the charging bay 5 and the superpixel 25a representative of the hottest area of the ICE vehicle 6 is 20 degrees Celsius. Comparatively, with reference to FIG. 6b, the thermal variation between the superpixels 26i, 26j, 26k, 26l representative of the charging bay 5 and the superpixel 26a representative of the hottest area of the EV 2 is 3 degrees Celsius. Using this method, examining temperature variation rather than actual temperature, allows for variation in ambient temperature. For example, on a hot day, the bonnet 10 of an EV 2 will be at a higher temperature due to the sun rather than the heat generated by the EV 2.

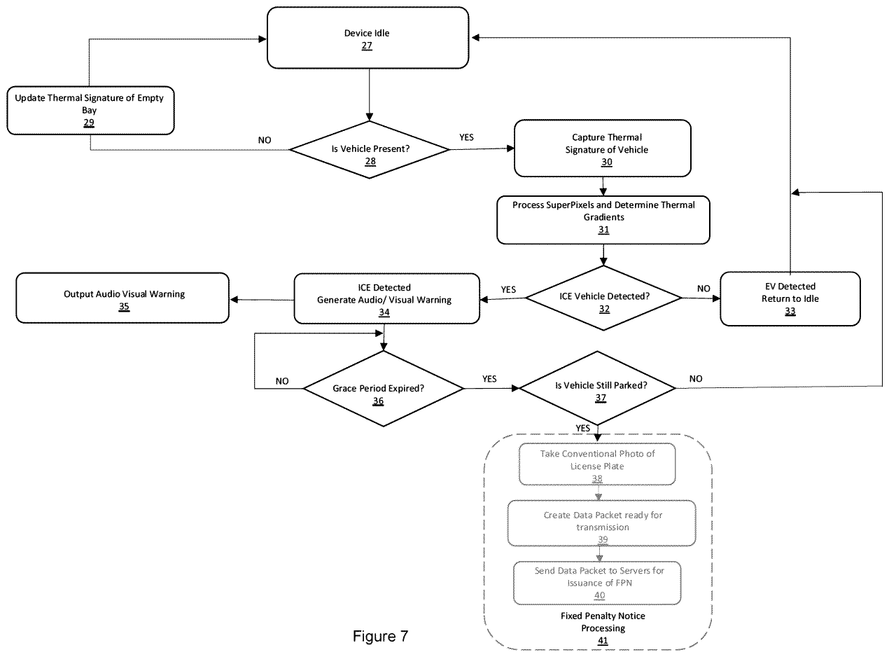

With reference to FIG. 7, there are illustrated methods of using the system 100. In FIG. 7, the system 100 initially determines 28 if a vehicle is present in the monitored EV charging bay 5. If no vehicle is present, the system 100 updates 29 the thermal signature of the empty bay 5 before returning to being idle 27. If a vehicle is found to be present, the thermal signature of the vehicle is captured 30.

The system 100 is configured to then process 31 the thermal capture to calculate superpixels 25, 26 and accordingly to determine the thermal gradients of the thermal capture. Based upon the output of this process, and comparison with a background calibration image 14 or user defined values, the system 100 is configured to identify 32 if the vehicle is an ICE 6 or an EV 2. If an EV 2 is detected, the system returns 33 to idle. Alternatively, if an ICE 6 is detected an audio/visual warning is generated 34 and output 35 by the system 100. Upon issuing the warning, a grace period timer 19 is initiated. The system 100 is arranged to check 36 if the grace period has expired. Once the defined grace period has expired, the system 100 confirms 37 if the vehicle is still present. If the vehicle is no longer present in the charging bay 5, the system 100 returns to being idle 27. If the vehicle is found to still be present, the system is configured to initiate Fixed Penalty Notice (FPN) processing 41. Following initiation of this process, the conventional camera 21 is arranged to capture 38 a conventional photo of the license plate of the occupying vehicle. A data packet containing the photo along with any other additional relevant data, such as time stamps and thermal captures, is compiled 39. The data packet is then sent 40 to servers for issuance of an FPN.

In another arrangement, the system 100 may be configured to identify EVs 2 which have parked in an EV charging bay 5 but which have either not initiated a charging session or have remained parked in the charging bay 5 following completion of a charging session. The system 100 may, through a data connection with the charge point operator via open charge point protocol (OCPP) for the specific charging station 3, confirm whether a charging session has been initiated for the vehicle currently occupying the charging bay 5. Additionally, through connection via the OCPP standard, the system 100 may identify when a charging session was completed. The system 100 may be arranged to issue audio and/or visual warnings 18, as described above, for offending ICEs 6 as well as processing FPNs, optionally after a user or system 100 defined grace period. In providing a deterrent and penalty process, the system 100 reduces the delay caused by non-charging EVs 2 parking in EV charging bays 5 whilst also optimizing the output of the charging point 3, therefore benefitting both the EV 2 user and the operator.

The system 100 may be attached or integrated into a charging point 3, as shown in FIG. 1. The system 100 may also be independent to the charging point 3, such as wall mounted or attached to a designated apparatus. The system 100 may be attached to the charging point 3 associated with the EV charging bay 5 to be monitored. Examples of a selection of these possible locations are shown in FIG. 8. The system 100 may be arranged to detect a vehicle driving forwards or reversing into the charging bay 5. In the case of the vehicle driving forwards, an ICE 6 is identifiable by the heat generated in the front grille 9 and bonnet 10 area, as shown in FIG. 3a. In the case of the vehicle reversing, an ICE vehicle 6 is identifiable by the heat generated in the exhaust area 4 as shown in FIG. 11. Other areas are possible, for example a vehicle underside 110, as will be further described below.

The system 100 may comprise a display panel. For example, the system may comprise a low power e-ink display panel for visual notification when an ICE vehicle 6 enters the EV charging bay 5. E-ink display panels are known in the arts to use particularly low power, since images are refreshed only in connection with the processing of a new event. It is not within the remit of the present application, though, to describe e-ink display panels in detail. The system may be integrated with the charging station 3 and, therefore, display visual notifications on the screen of the charging station.

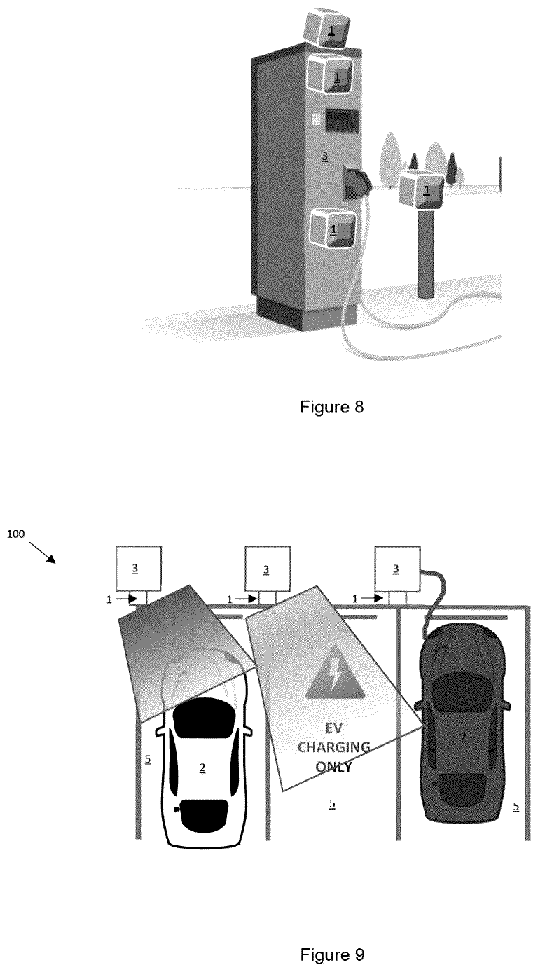

The system 100 may also be arranged at a plurality of orientations. For example, wherein a charging point 3 is positioned at the centre of the charging bay, the system 100 may be attached to the charging point 3 in a forward-facing orientation, as shown in FIG. 2. With reference to FIG. 9, the orientation of the system 100 may also be angled to detect a vehicle in a charging bay 5 which is offset from the charging point 3.

In a further arrangement, the system 100 may be arranged to monitor a plurality of charging bays 5. FIG. 10 is a thermal capture of two ICE vehicles 6 parked in two adjacent charging bays 5. Using the methods described previously, the system 100 may be configured to compare the heat distribution within the confines of the charging bay 5 markings before and during occupation by a vehicle. The system 100 may then be arranged to issue audio/visual warnings 18 and to transmit captured data via the methods described previously.

The system 100 may also be arranged to detect an ICE 6 while the vehicle 6 is in motion. FIG. 12 is a thermal capture comprising an ICE 6 driving on a road. The bonnet 10 temperature is shown as 32.8 degrees Celsius. FIG. 13 is a thermal capture of an EV 2 whilst driving on a road. The temperature of the bonnet 10 of the EV 2 is shown as 16.9 degrees Celsius. Using the analysis methods described previously, the system 100 may be arranged to identify an ICE 6 or EV 2 from the thermal captures of in motion vehicles. For example, the system 100 may be arranged to monitor vehicles entering a Zero Emissions Zone. Currently, Zero Emissions Zones are monitored by ANPR cameras which require significant levels of infrastructure to be effective, and may be ineffective in identifying vehicles with number plates from outside the country in which the ANPR camera is deployed. Advantageously, the system 100 is arranged to identify an EV 2 based upon a thermal capture of a vehicle and is therefore independent of the number plate. The system 100 may also transmit a conventional camera capture of the vehicle, allowing manual identification for onwards penalty issuing in lieu of recognition by ANPR.

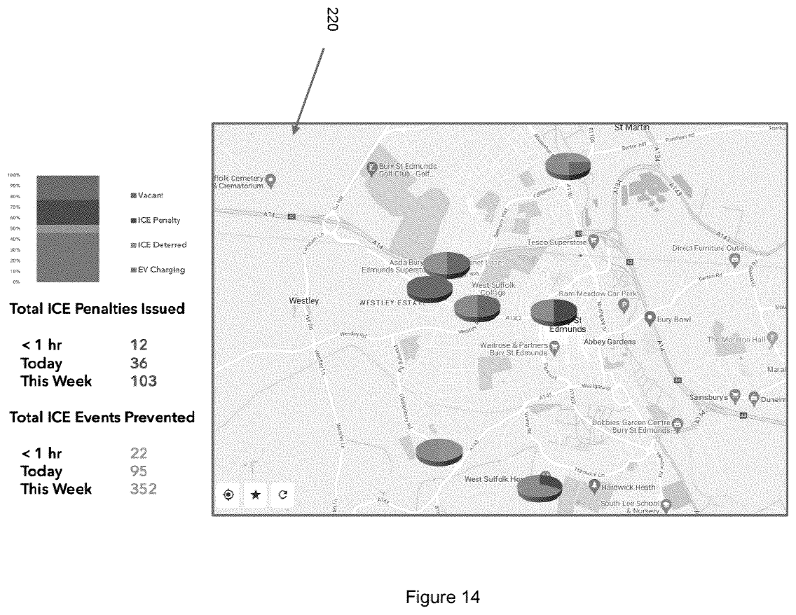

Further, FIG. 14 shows on a map the approximate location of seven EV charging facilities having EV charging bays as described herein. Each EV charging facility is represented by a pie chart, and each pie chart summarizes the statuses of the EV charging points 3 present at each EV charging facility. As described herein, said charging points may be in use (“EV charging”) or “vacant”, these representing the statuses considered to be legitimate by the system 100. However, there may have been attempts from ICEs 6 to illegitimately use said facilities. Accordingly, there may be EV charging bays 5 having a status of “ICE Deterred” or “ICE Penalty”, depending on which course of action is adopted following the detection of an ICE 6 as described hereinabove. The skilled user will recognize that the data captured from the plurality of devices 1 deployed using the equipment described in system 100 will result in valuable ‘big data’ for further analysis by the operators of the charging points 3 to better understand the behavior of drivers and to plan for future deployments. FIG. 14 is a graphical representation 220 of a status of the system 100 described hereinabove, which is based on the deployment of data acquisition boxes 1 as also described hereinabove. Below, we describe a further computerized system 210, based on a different type of parking sensor-which we refer to as “parking-sensor puck”.

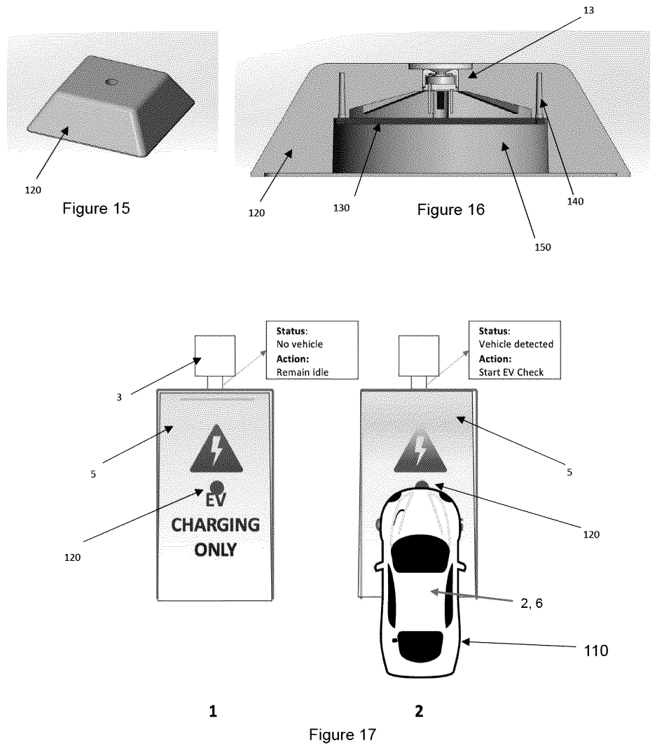

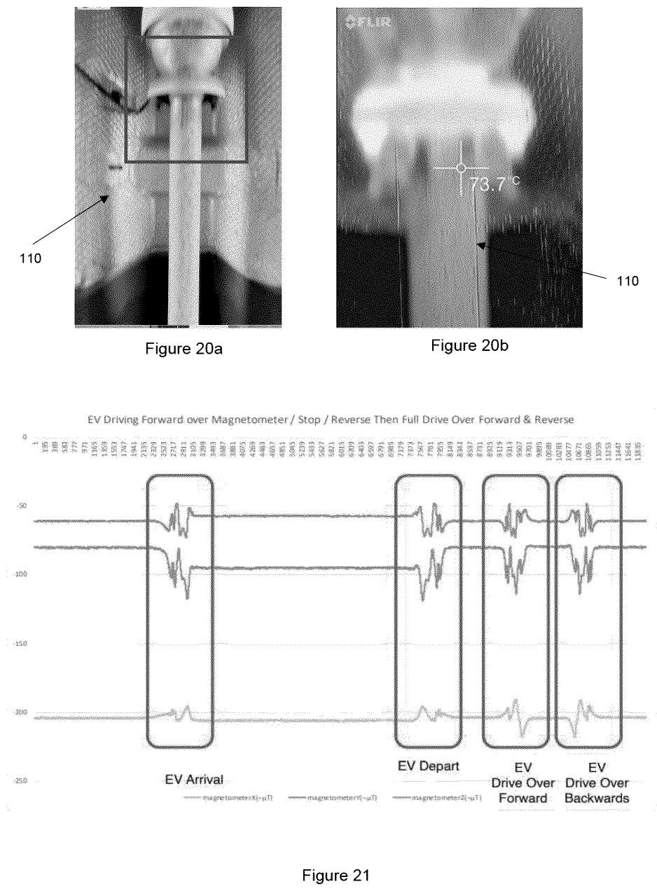

In alternative arrangements, which may be advantageous for certain configurations of charging bays 5 such as on-street parking where the layout of the charge point 3 relative to the charging bay 5 may be more challenging than the typical layout as seen, for example, in rapid charging stations, the at least one thermal imaging camera 13 may be replaced by a parking-sensor puck 120 which may, for example, be affixed to the ground in the middle of the parking bay 5 to be monitored. An example of such parking-sensor puck 120 is shown in FIGS. 15 and 16, with FIG. 16 illustrating the most important component of the parking-sensor puck 120, being a miniature thermal imaging camera 13, a three-axis magnetometer 130 and a wireless transmitter 140. The thermal imaging camera 13, in the presence of a parked vehicle 2, 6, whether an EV 2 or an ICE 6, will face the vehicle underside 110. The vehicle underside 110 is shown schematically in FIG. 17 and is also indicated in FIG. 11. FIGS. 20a and 20b also relate to a vehicle underside 110.

The design of the parking-sensor puck 120 may share many similarities with existing commercial devices used for monitoring bay occupancy within smart-city applications, such as the Bosch Parking Lot Sensor, at the time of writing described at URL: https://www.bosch-connectivity.com/products/connected-mobility/parking-lot-sensor/downloads/, which uses a combination of magnetometer 130 and radar to determine solely if a vehicle is parked in the bay. However, the novel parking-sensor puck 120 described herein may comprise an array of sensors which are used to determine:
a) the presence/absence of a vehicle 2, 6, as known;
b) when a vehicle 2, 6 is detected, whether that vehicle is an EV 2 or ICE 6, similar to the determination made hereinabove using solely a thermal imaging camera 13; and
c) when an EV 2 is detected, whether the EV 2 is charging or not.

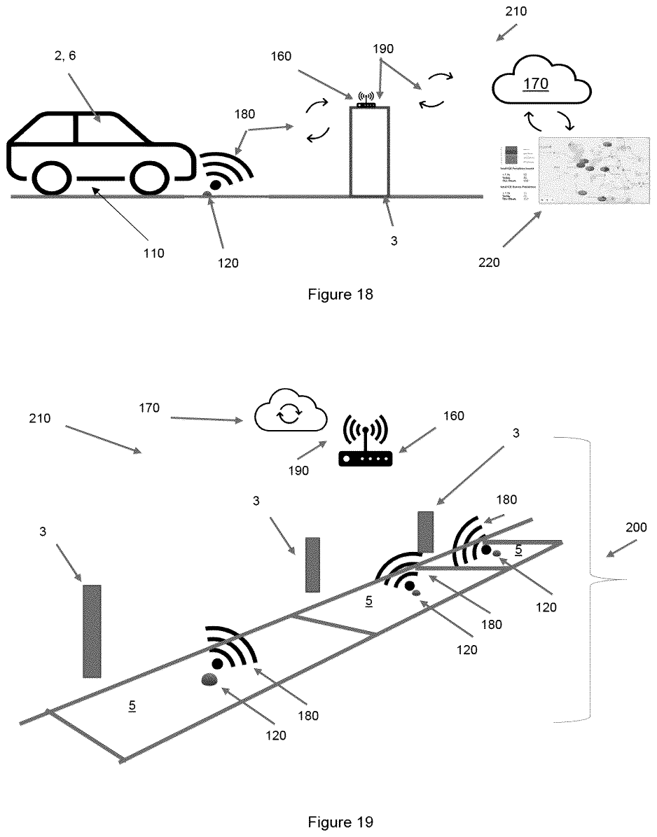

Data gathered by one or more parking-sensor pucks 120 may be transmitted via the associated wireless transmitters 140 (options include via cellular, LoRaWan or the preferred Bluetooth Low Energy (BLE) connections 180) to at least one server 170 (shown in FIGS. 18 and 19) via a gateway 160 (also shown in FIGS. 18 and 19). In a preferred arrangement using BLE 180, the gateway 160 may receive status change messages from the one or more parking-sensor pucks 120 and then forward this onto the server(s) 170 (which may, for example, be cloud servers 170) using either cellular, local WiFi access poiont or LoRaWan based communications 190, as shown in FIGS. 18 and 19. This has the advantage of keeping the costs and power consumption of the parking-sensor puck 120 low, and allowing for rapid deployment, especially if a battery powered gateway 160 is used.

The parking-sensor puck 120 may contain one or more of the following sensors and components:
Passive infrared sensor (not shown)—which may be used as an optional, initial ultra-low power detection of whether anything is present above the parking-sensor puck 120; once triggered, the passive infrared sensor may be used to enable the other, higher power sensing solutions embedded in the parking-sensor puck 120 to determine that it is indeed a vehicle 2, 6 that is parked on the parking bay 5 and not some other obstruction; then, the vehicle type/status may also be determined as will be described below.
Thermal sensor—this may be one of a number of different options ranging from:
   one or more simple pyroelectric infrared sensing elements such as those at the time of writing available from URL: https://www.murata.com/en-eu/products/sensor/overview/item/ira_imlseries;
   one or more ‘array’ type thermal sensors such as the thermal array sensors described at the time of writing at URL:
   https://www.melexis.com/en/product/MLX90640/Far-Infrared-Thermal-Sensor-Array, which produces an array of 32×24 temperature pixels over the target area;
   a standard thermal imaging sensor 13, such as a sensor commonly used within thermal imaging cameras 13, such as the FLIR Lepton thermal camera mentioned hereinabove.
Magnetometer 130—a three-axial magnetometer 130 may measure changes in magnetic field caused by the presence and movement of ferrous materials contained within the parked vehicle 2, 6 as well as the various electric fields generated from components within the vehicle such as the alternator in an ICE 6 or the EV motors and charging inverters in an EV 2.
Optional GNSS (not shown)—by knowing the position of the parking-sensor puck 120 this can provide assistance in the deployment of the parking-sensor pucks 120 as less registration effort is required when installing.
Battery 150—this could either be a primary battery (such as a lithium thionyl chloride) type cell or it could be a rechargeable battery with solar cells on the top surface of the sensor puck to allow energy to be harvested from the sun/artificial lighting. This offers a number of options for deployment in locations that are outside or within enclosed parking structures such as car parks.
Wireless transmitter 140—as previously described, depending upon the use case, the parking-sensor puck 120 could have its own self-contained Low Power Wide Area (LPWA) radio transmitter 140 using either licensed cellular transmission 180 such as LTE CatM/NB-IOT 180 or unlicensed bands such as LoRaWAN 180. However, as charging bays 5 tend to be installed in groups of more than a single unit, it is advantageous from a cost perspective to simplify the radio element 180 within the parking-sensor puck 120 to use a beacon or gateway configuration using BLE connections 180. One such option is the InPlay IN100 NanoBeacon, at the time of writing available from URL: https://inplay-tech.com/in100, which contains an inbuilt state machine allowing the parking-sensor puck 120 to transmit beacon messages only when certain conditions are met, thereby significantly reducing the power consumption of the device 120. A single gateway 160, equipped with a LPWA radio connection 190 and the ability to receive the BLE beacon messages 180 from several hundred parking-sensor pucks 120 at once would be more than sufficient to cater for even the largest envisioned current charging hub location, but additional gateways 160 could always be added to expand the number of parking-sensor pucks 120 that can be serviced, should this prove necessary.

Whilst a parking-sensor puck 120 as described herein retains the ability of the previously described solution to process thermal data in a similar way, the location of the parking-sensor puck 120 underneath the vehicle 110 allows the detection of an even greater thermal differential between ICEs 6 and EVs 2. After only a few moments of the engine running, the exhaust system (and thus the vehicle underside 110) of a typical ICE 6 heats up to over 70 degrees C and can get as high as several hundred degrees at the hottest points and dependent upon how hard the engine has been run. FIGS. 20a and 20b have been included to illustrate this point. This generates hotspots on the underside of the vehicle 110 with considerable variation in temperature. By way of contrast, a typical EV 2 has an underneath temperature which is generally close to the ambient temperature even after running for some time and which is consistent. These observations allow the parking-sensor puck 120 described herein to easily differentiate between ICE 6 and EV 2 based purely on their thermal signature in a similar way to the previously described arrangement 100. However, in the present arrangement 210, which is based on the use of the described parking-sensor pucks 120, including magnetometer data (such as those shown in FIGS. 21, 22 and 23) provides an additional source of information which can be used advantageously at least to:
A) verify whether the vehicle is indeed an ICE 6 or EV 2; and,
B) provide new information about whether an EV 2 is charging or not whilst in the parking bay 5.

FIG. 21 shows three signals referring to the x, y and z components of the magnetic field measured by the magnetometer 130 incorporated into the parking-sensor puck 120 of FIGS. 15 and 16 in connection with two EV 2 parking events. It can be seen how the EV arrival and departure events, respectively, as represented by the magnetometer signals, are specular in time and therefore distinguishable.

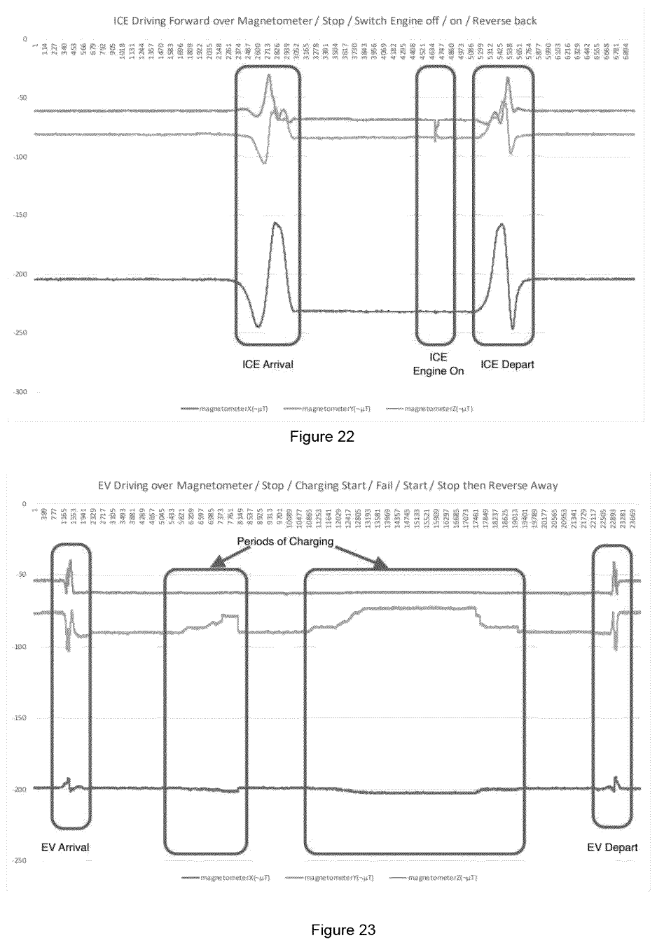

FIG. 22 shows three signals referring to the x, y and z components of the magnetic field measured by the same magnetometer of FIG. 21, though in connection with a single ICE 6 parking event. The specular nature of the tracks in conjunction with the arrival and departure of the ICE 6 is still visible. In addition, it seems possible to distinguish an event corresponding to the switching-on of the ICE 6.

Accordingly, selective determination between EV 2 or ICE 6 at the parking bay 5 equipped with the described parking-sensor puck 120 can in principle be carried out by the computerized system 210 using the thermal signature or magnetic signature of the vehicles 2, 6 as detected by a parking-sensor puck 120—independently. It will be appreciated, however, that these distinct methods may advantageously be ‘fused’, resulting into greater reliability. For example, one method could be used to validate the outcome obtained by the other, or the two methods could be used in parallel, in the context of a chosen selective-determination algorithm. The present application, however, does not extend to describing specific detection algorithms.

Magnetometer signals as shown in FIG. 23, that is during EV charging, also show a clear pattern during the charging cycle which can be used as an indication of whether the EV 2 is being charged or is simply an EV 2 which is parked in the bay-either without any attempt to charge or where it has finished charging and the owner has not returned to move it away so that another EV driver can make use of the charging facility, which could be monetized into an ‘overstay’ penalty to encourage the timely freeing up of charging infrastructure. This may also be beneficial in fleet depot charging scenarios, where fleet managers may wish to understand the ‘overstay’ of fleet vehicles and optimize the rotation of vehicles during their time at the depot. The signals in FIG. 20 refer to an EV 2 driving over a parking-sensor puck 120 as described herein, and then stopping before attempting a charge. This first attempt fails after a few seconds, and a second charging session is initiated which completes after a period of time. The EV 2 then reverses away from the parking-sensor puck 120. In this orientation, the magnetometer z axis gives an indication of the kW charge rate being delivered by the charger 3 (shown in FIGS. 17, 18 and 19), which could also be used advantageously to provide additional data. FIG. 18 shows a graphical representation 220 of the status of the system 210, which includes charge time statistics, amongst other data (see also FIG. 14).

In a further arrangement 210, in a situation where EV charging bays 5 are designated for specific users as opposed to general EV drivers, such as licensed taxis and resident charging zones, the parking-sensor puck solution 210 described herein would allow, with the simple addition of a BLE beacon placed in the authorized vehicle, for the vehicle's authorization-to-charge to be verified. Once the vehicle has been confirmed as an EV 2, the gateway 160 (shown in FIGS. 18 and 19) would also check for the newly discovered presence of an EV-authorizing BLE beacon which would identify the vehicle charging. Should the beacon not be present, a similar penalty enforcement process to the ICE vehicle scenario described hereinabove could be enacted. In FIG. 19, reference number 200 indicates a subsystem of the overall computerized system 210. This system 200 comprises the parking-sensor pucks 120 in operable communication with the gateway device 160 via a communication network 180 as described herein.

The first arrangement 100 described above is based on computations performed directly on the parking devices/boxes 1, via appropriate processors. The second arrangement 210 described above is based on computations performed on one or more servers 170. The skilled person would appreciate that the location of the processing could however be easily switched, depending on preference and/or any specific applications.

The singular terms “a” and “an” should not be taken to mean “one and only one”. Rather, they should be taken to mean “at least one” or “one or more” unless stated otherwise.

The word “comprising” and its derivatives including “comprises” and “comprise” include each of the stated features but does not exclude the inclusion of one or more further features.

The above implementations have been described by way of example only, and the described implementations are to be considered in all respects only as illustrative and not restrictive.

It will be appreciated that variations of the described implementations may be made without departing from the scope of the present disclosure.

It will also be apparent that there are many variations that have not been described, but that fall within the scope of the appended claims.

### LIST OF REFERENCES

1 Data acquisition box
2 Electric Vehicle (EV)
3 EV charging point
4 Exhaust
5 EV charging space or bay
6 Internal Combustion Engine vehicle (ICE)
7 Physical presence sensor range
8 Thermal camera range
9 Front grille
10 Bonnet
11 Physical presence sensor
12 Vehicle presence detection
13 Thermal imaging camera
14 Background calibration input
15 Thermal image processing module
16 EV/ICE determination module
17 ICE detected
18 Audio/Visual alert of impending penalty if vehicle is not moved
19 Grace period timer
20 Module to check if ICE is still parked
21 Conventional camera
22 Image capture module
23 ICE detected and grace period expired
24 Photo evidence and meta data prepared and sent via cellular radio to Electric Vehicle Management (EVM) servers for Fixed Penalty Notice (FPN) processing
25 Superpixels derived from thermal image of EV
26 Superpixels derived from thermal image of ICE vehicle
27 Device idle
28 Checking if vehicle is present
29 Updating thermal signature of empty bay
30 Capturing thermal signature of vehicle
31 Processing superpixels and determining thermal gradients
32 Checking if ICE vehicle is detected
33 EV detected and returning to idle
34 ICE detected and audio/visual warning detected
35 Output of audio/visual warning
36 Checking if grace period has expired
37 Checking if vehicle is still parked
38 Taking conventional photo of license plate
39 Creating data packet
40 Sending data packet to servers
41 FPN processing
100 System
110 Vehicle underside
120 Parking-sensor puck
130 Magnetometer
140 Wireless transmitter
150 Battery
160 Gateway
170 Server
180 Connection between parking-sensor puck and gateway
190 Connection between gateway and server
200 System comprising parking-sensor pucks and gateway
210 Computerized system comprising one or more servers
220 Graphical representation of a status associated with the computerized system

1. A parking-sensor puck for selectively determining access of an electric vehicle (EV) or of an internal combustion engine (ICE) vehicle into a parking bay, the parking sensor puck comprising:
a thermal sensor configured to measure at least one value representative of a temperature on an underside of said vehicle;
a magnetometer configured to measure at least one value representative of magnetic field present at the parking sensor puck; and, a wireless transmitter for communicating said values to a server.

2. The puck of claim 1, further comprising a passive infrared sensor configured to detect presence of an obstruction located in the space above the puck, and to awake the thermal sensor and/or the magnetometer in the presence of said obstruction.

3. The puck of claim 1 or 2, wherein the thermal sensor is a pyroelectric sensor.

4. The puck of claim 1 or 2, wherein the thermal sensor is an array-type infrared thermal sensor comprising an array of pixels configured to acquire a plurality of corresponding values representative of a plurality of corresponding temperatures taken on said vehicle underside.

5. The puck of claim 4, wherein the array-type infrared thermal sensor is an infrared thermal imaging camera configured to acquire a thermal image of at least a portion of said vehicle underside.

6. The puck of any preceding claim, wherein the magnetometer is a three-axis magnetometer.

7. The puck of any preceding claim, further comprising a GNSS sensor.

8. The puck of any preceding claim, further comprising a battery.

9. The puck of claim 8, wherein the battery is rechargeable.

10. The puck of claim 9, further comprising a light-harvesting device configured to recharge said rechargeable battery, optionally wherein said light-harvesting device is configured to harvest solar light.

11. The puck of any preceding claim, wherein the wireless transmitter is configured to communicate said values over one or more of the following connections: a Low Power Wide Area (LPWA) radio connection using either a licensed cellular transmission such as LTE CatM/NB-IOT or unlicensed bands such as LoRaWAN; and, a BLE connection.

12. A system comprising a plurality of parking-sensor pucks in accordance with any one of claims 1 to 11, and at least one gateway for collecting the values from the plurality of parking-sensor pucks and for forwarding said values to the server;
optionally, wherein the at least one gateway and the plurality of parking-sensor pucks are configured to communicate over a BLE connection;
optionally, wherein the gateway is configured to communicate to the server over one or more of the following connections: a Low Power Wide Area (LPWA) radio connection using either a licensed cellular connection such as a LTE CatM/NB-loT connection, or unlicensed bands such as a LoRaWAN connection; and, a WiFi connection to a nearby access point.

13. A computerized system for managing access of electric vehicles (EVs) or of internal combustion engine vehicles (ICEs) into parking bays, the system comprising:
at least one parking-sensor puck according to any one of claims 1 to 11 in operable communication with at least one server, each parking-sensor puck being installed on a corresponding parking bay; and/or
at least one system according to claim 12 in operable communication with at least one server, each parking-sensor puck being installed on a corresponding parking bay;
wherein the computerized system is configured to selectively determine whether an EV or an ICE vehicle has entered a parking bay based on a processing of at least one of said values measured by a corresponding parking-sensor puck.

14. The computerized system of claim 13 when dependent from any one of claims 4 and 5, wherein said processing comprises determining one or more parameters calculated from said values representative of a plurality of temperatures taken on said vehicle underside;
optionally, wherein said processing comprises a comparison of said one or more parameters with one or more respective reference values for said parameters;
optionally, wherein said reference values comprise one or more respective background values acquired prior to the vehicle accessing said parking bay, and preferably immediately before said vehicle has accessed said parking bay;
optionally, wherein said one or more parameters comprise at least one of a difference, a gradient, a peak and a mean.

15. The computerized system of claim 14, wherein said processing comprises defining one or more superpixels of either said thermal image or of said array of pixels, each superpixel comprising a cluster of neighbouring pixels satisfying a predetermined variance criterion.

16. The computerized system of claim 15, wherein said parameters and/or reference values are calculated across said superpixels.

17. The computerized system of any one of claims 13 to 16, wherein the system is configured to determine whether the EV is charging if the system has determined that an EV has entered the parking bay.

18. The computerized system of any one of claims 13 to 17, wherein the system is configured to initiate a penalty process if the system has determined:
that an ICE has entered the parking bay; or,
that an EV that has entered the parking bay is not charging.

19. The computerized system of any one of claims 13 to 18, wherein the system is configured to monitor usage of the parking bays by the EVs and ICEs.

20. A computerized method of managing access of electric vehicles (EVs) or of internal combustion engine vehicles (ICEs) into parking bays using the computerized system of any one of claims 13 to 19, the method comprising:
using a parking-sensor puck, measuring at least one value representative of a temperature on the vehicle underside and at least one value representative of a magnetic field at the parking-sensor puck;
using said server, processing said at least one temperature value and/or magnetic field value;
based on said processing of said at least one temperature and/or magnetic field value, determining whether an EV or an ICE has entered the corresponding parking bay.

21. The computerized method of claim 20, further comprising:
based on said processing of said at least one temperature and/or magnetic field value, determining whether the EV is charging if the system has determined that an EV has entered the parking bay.

22. The computerized method of claim 21, further comprising initiating a penalty process if the system has determined that an ICE has entered the parking bay or that an EV that has entered the parking bay is not charging.

23. The computerized method of claim 20, 21 or 22, further comprising:
based on said processing of said at least one temperature and/or magnetic field value, monitoring the usage of the parking bays by said EVs and ICEs.

24. One or more computer readable media comprising coded instructions implementing, when executed by a computer, a method according to any one of claims 20 to 23.

25. A computerized system for selectively determining access of an electric vehicle (EV) or of an internal combustion engine vehicle (ICE) into a predetermined zone of interest, the system comprising:
at least one thermal imaging camera configured to acquire at least one thermal image, said thermal image comprising at least a portion of said vehicle after said vehicle has accessed said predetermined zone of interest, and, in addition, at least a region of said predetermined zone of interest,
wherein the system is configured to perform said selective determination based on a processing of said thermal image.

26. The system of claim 25, wherein said predetermined zone of interest comprises one or more EV charging bays;
alternatively, wherein said interest zone comprises a restricted traffic zone, such as a Low Emission Zone.

27. The system of claim 26, wherein the system comprises one or more EV charging points;
optionally, wherein each EV charging point is associated to a respective EV charging bay.

28. The system of claim 27, wherein each thermal imaging camera is installed in, within, or on a respective EV charging point, or at a location nearby said respective EV charging point;
preferably, wherein said thermal imaging camera is integrally provided with said EV charging point;
preferably, wherein said thermal imaging camera is adapted to be retro-fitted to said EV charging point.

29. The system of claim 26, 27 or 28, wherein each thermal imaging camera is associated with a respective one, and only one, EV charging bay.

30. The system of any one of claims 25 to 29, wherein the at least one thermal imaging camera is configured to capture, and the system is configured to identify, at least a first portion belonging to one or more of:
a vehicle's bonnet;
a vehicle's grille; and
a vehicle's rear side,
as well as:
a second portion belonging to a remainder of the vehicle's body.

31. The system of any one of any one of claims 25 to 30, wherein said processing comprises the determination of one or more parameters calculated from values representative of respective temperatures associated with said thermal image.

32. The system of claim 31, wherein said processing comprises a comparison of said one or more parameters with one or more respective reference values for said parameters.

33. The system of claim 32, wherein said reference values are derived from a background thermal image acquired prior to the vehicle accessing said interest zone, and preferably immediately before said vehicle has accessed said interest zone.

34. The system of claim 32, wherein said reference values are derived from a subset of said values representative of respective temperatures associated with said thermal image, said subset relating to said region of the interest zone.

35. The system of any one of claims 31 to 34, wherein said one or more parameters comprise at least one of the following:
a difference;
a gradient;
a peak; or
a mean.

36. The system of any one of claims 25 to 35, wherein said processing comprises the definition of one or more superpixels of said thermal image, each superpixel comprising a cluster of neighbouring pixels of said thermal image satisfying a predetermined variance criterion.

37. The system of claim 26 and any one of claims 31 to 34, wherein said parameters and/or reference values are calculated across said superpixels.

38. The system of any one of the preceding claims, the system further comprising a sensor configured to sense ingress of said vehicle into said interest zone.

39. The system of claim 38, wherein said sensor has a greater spatial range than that of said thermal imaging camera, such that the system is configured to sense the ingress of said vehicle into said interest zone before the acquisition of said at least one thermal image.

40. The system of any one of claims 25 to 39, the system further comprising, or said sensor being, a camera configured to acquire one or more visual images of said vehicle after it has entered said interest zone;
optionally, wherein the system is configured to process said one or more visual images to ascertain that it is a vehicle that has entered said interest zone;
optionally, wherein said visual image processing comprises using a deep neural network trained to recognize vehicles.

41. The system of any one of claims 25 to 40, wherein the system is configured to produce a deterrent audio/visual output and/or to initiate a penalty process if the system has determined that an ICE vehicle has entered the interest zone.

42. The system of claim 41, wherein said deterrent audio/visual output comprises information related to a predetermined grace time period for avoiding said penalty process.

43. The system of claim 42, wherein said penalty process is initiated by the system after the production of said deterrent audio/visual output, if the ICE that has entered the interest zone has not left the interest zone after a predetermined grace time period.

44. A method of selectively determining access of an EV or of an ICEe into a predetermined zone of interest, the method comprising:
using at least one thermal imaging camera, acquiring at least one thermal image, said thermal image comprising at least a portion of said vehicle after said vehicle has accessed said predetermined zone of interest, and, in addition, at least a region of said predetermined zone of interest;
processing said at least one thermal image; and,
based on said processing, performing said selective determination.

45. The method of claim 44, wherein said predetermined zone of interest comprises one or more EV charging bays;
alternatively, wherein said interest zone comprises a restricted traffic zone, such as a Low Emission Zone.
